(19) United States
(12) Patent Application Publication
(10) Pub. No.: US 2025/0343099 A1
(43) Pub. Date: Nov. 6, 2025

(54) Hybrid Material Lid, Heat Sink, or Cold Plate for Semiconductor Packages

(71) Applicant: NVIDIA Corporation, Santa Clara, CA (US)

(72) Inventors: Padam Jain, San Jose, CA (US); Ronilo Boja, Gilroy, CA (US); Shantanu Kalchuri, San Jose, CA (US)

(73) Assignee: NVIDIA Corporation, Santa Clara, CA (US)

(21) Appl. No.: 19/171,233

(22) Filed: Apr. 5, 2025

Related U.S. Application Data
(60) Provisional application No. 63/643,252, filed on May 6, 2024.

(51) Int. Cl. H01L 23/367; H01L 21/50; H01L 23/00; H01L 23/373; H01L 25/07

(52) U.S. Cl. CPC H01L 23/3675; H01L 21/50; H01L 23/3735; H01L 24/32; H01L 25/072; H01L 23/3732; H01L 23/3737; H01L 2224/32225

(57) ABSTRACT

Heat transfer apparatus may include an integrated circuit (“IC”) package that itself includes a package substrate and one or more dies coupled to the package substrate such that bottom surfaces of the dies face toward the package substrate and top surfaces of the dies define die top areas. A metal member, such as a package lid, a heat sink, or a cold plate, may be designed to fit above at least part of the package substrate. A heat transfer member having a higher thermal conductivity than the metal member is attached to the metal member such that the heat transfer member is disposed over a die top area when the metal member is placed over the package substrate. In some embodiments, the heat transfer member may comprise a diamond material.

### CROSS REFERENCE TO RELATED APPLICATIONS

This application claims benefit to the filing date of prior U.S. Patent Application No. 63/643,252, filed on 2024 May 6 (the “Provisional Application”), the contents of which are hereby incorporated by reference as if entirely set forth herein. In the event of conflict between the meaning of a term used in this document and the same or a similar term used in the Provisional Application or in another document incorporated herein by reference, the meaning associated with this document shall control.

### BACKGROUND

Most integrated circuit (“IC”) packages include a package substrate onto which one or more silicon IC dies, also commonly called “chips,” are mounted. In addition to serving as a structural foundation for an IC package, the package substrate also provides electrical connections between the dies and an array of pins or other electrical contacts that are accessible on the outside of the package. For this reason, the substrate resembles a small multilayer printed circuit board. Package substrates may be constructed from a variety of materials. By way of example, many package substrates are made from a woven glass reinforced epoxy laminate commonly referred to as “FR4” to denote its flame retardant characteristics. Other materials are also used.

Because the circuitry in a die generates heat while operating, often a heat sink or a cold plate is attached to an IC package in one way or another to help dissipate the heat that is generated by the dies in the package. In many IC packages, a thermally conductive package lid covers the package substrate and the dies. In such cases, a heat sink or cold plate may be placed in contact with the package lid. In other IC packages, no package lid is used, and the dies are left exposed. In the latter cases, a heat sink or cold plate may be placed in direct contact with the dies. In any such applications, it is generally desirable to decrease the thermal resistance of the heat transfer path between the silicon in the IC package and the heat sink or the cold plate.

For IC packages that include a lid, the lid is traditionally made from a metal such as copper. Copper exhibits relatively good thermal conductivity, has good mechanical robustness, is relatively easy to fabricate into large three-dimensional (“3D”) shapes, and is relatively affordable. Despite these favorable characteristics of copper, however, thermal dissipation continues to be a challenge in many high performance IC chip applications. For example, thermal dissipation can be especially challenging in high performance chips designed for machine learning and artificial intelligence use cases, in which higher power capability translates into higher performance for the chip package.

While several materials are known that exhibit much higher thermal conductivity than copper, such materials are more expensive and are less mechanically robust than copper. In addition, such materials are difficult to use in the fabrication of large components that have 3D shapes such as, for example, an IC package lid.

A need therefore exists for affordable and practical IC packaging techniques that can decrease the thermal resistance of the heat path between the silicon in the package and a heat sink or cold plate.

### BRIEF DESCRIPTION OF THE DRAWINGS

Several example embodiments will be described below with reference to the following figures, in which like reference numbers are used to denote the same or similar elements.

FIG. 1 is a sectional side view illustrating an example hybrid material IC package lid in accordance with embodiments.

FIG. 2 is a sectional side view illustrating an example IC package substrate with dies mounted thereon in a manner suitable for use with the package lid of FIG. 1.

FIG. 3 is a sectional side view illustrating an example assembled IC package that includes the elements of FIGS. 1 and 2 in accordance with embodiments.

FIG. 4 is a sectional side view illustrating an example hybrid material heat sink or cold plate in accordance with embodiments.

FIG. 5 is a sectional side view illustrating an example lidless IC package substrate with dies mounted thereon in a manner suitable for use with the heat sink or cold plate of FIG. 4.

FIG. 6 is a sectional side view illustrating an example assembled IC package that includes the elements of FIGS. 4 and 5 in accordance with embodiments.

FIG. 7 is a sectional side view illustrating a second example assembled IC package formed with a hybrid material package lid in accordance with embodiments.

FIG. 8 is a sectional side view illustrating a third example assembled IC package formed with a hybrid material package lid in accordance with embodiments.

FIG. 9 is a sectional side view illustrating a third example assembled IC package formed with a hybrid material package lid in accordance with embodiments.

FIG. 10 is a sectional side view illustrating a second example assembled IC package formed with a hybrid material heat sink or cold plate in accordance with embodiments.

FIG. 11 is a sectional side view illustrating a third example assembled IC package formed with a hybrid material heat sink or cold plate in accordance with embodiments.

FIG. 12 is a sectional side view illustrating a fourth example assembled IC package formed with a hybrid material heat sink or cold plate in accordance with embodiments.

FIG. 13 is a sectional side view illustrating an example package lid having a recess formed therein for receiving a heat transfer member in accordance with embodiments.

FIG. 14 is a top view of the example package lid of FIG. 13.

FIG. 15 is a sectional side assembly view illustrating attachment of a heat transfer member in the recess of the package lid of FIGS. 13 and 14 in accordance with embodiments.

FIG. 16 is a top view illustrating an example package lid having a through hole formed therein in accordance with embodiments.

FIG. 17 is a section side view of the package lid of FIG. 16 and a heat transfer member configured to fit in the through hole of the package lid.

FIG. 18 is a sectional side assembly view illustrating the heat transfer member of FIG. 17 assembled into the through hole of the package lid of FIGS. 16 and 17 in accordance with embodiments.

FIG. 19 is a sectional side view illustrating an example assembled IC package formed with the package lid of FIGS. 16-18 in accordance with embodiments.

FIG. 20 is a top view illustrating an example package lid having two through holes formed therein in accordance with embodiments.

FIG. 21 is a sectional side view of the package lid of FIG. 20 and two heat transfer members configured to fit in the through holes of the package lid.

FIG. 22 is a sectional side view illustrating an example assembled IC package formed with the package lid of FIGS. 20-21 in accordance with embodiments.

FIG. 23 is a flow diagram illustrating example methods for manufacturing heat transfer apparatus in accordance with embodiments.

### DETAILED DESCRIPTION

This disclosure describes multiple embodiments by way of example and illustration. It is intended that characteristics and features of all described embodiments may be combined in any manner consistent with the teachings, suggestions, and objectives contained herein. Thus, phrases such as “in an embodiment,” “in one embodiment,” and the like, when used to describe embodiments in a particular context, are not intended to limit the described characteristics or features only to the embodiments appearing in that context. Although numerous specific example embodiments are described below, it in intended that any on or more of the features or elements of each described embodiment may be combined with or substituted for any one or more of the features or elements of another described embodiment, in any desired combinations. The scope of the disclosure is intended to include all such combinations, modifications, and generalizations as well as their equivalents.

The phrases “based on” or “based at least in part on” refer to one or more inputs that can be used directly or indirectly in making some determination or in performing some computation. Use of those phrases herein is not intended to foreclose using additional or other inputs in making the described determination or in performing the described computation. Rather, determinations or computations so described may be based either solely on the referenced inputs or on those inputs as well as others.

The phrase “configured to” as used herein means that the referenced item, when operated, can perform the described function. In this sense, an item can be “configured to” perform a function even when the item is not operating and therefore is not currently performing the function. Use of the phrase “configured to” herein does not necessarily mean that the described item has been modified in some way relative to a previous state.

“Coupled” as used herein refers to a connection between items. Such a connection can be direct or can be indirect, such as through connections with other intermediate items.

Terms used herein such as “including,” “comprising,” and their variants, mean “including but not limited to.”

Articles of speech such as “a,” “an,” and “the” as used herein are intended to serve as singular as well as plural references except where the context clearly indicates otherwise. For example, articles of speech such as “a,” “an,” and “the,” when used in a claim or sentence subsequent to words such as “including,” “comprising,” or their variants, mean “one or more.”

### Materials

A variety of example embodiments will be described below in which a metal member is designed to be placed over a package substrate and in which a heat transfer member is attached to the metal member.

In some embodiments, the metal member may comprise an IC package lid. In other embodiments, the metal member may comprise a heat sink or a cold plate. Other embodiments are also possible. In any of the example embodiments to be described, the metal member may be made from any of a variety of metal materials that exhibit good mechanical reliability and that have reasonably light weight. By way of example, the metal member may be made from copper (possibly with an external coating such as a nickel coating), or from a copper-molybdenum (Cu—Mo) alloy, or from a copper-tungsten (Cu—W) metal matrix composite, or from an aluminum-silicon carbide (Al—SiC) metal matrix composite. Other materials, such as aluminum, may also be used. The thermal conductivity of copper is approximately 400 W/mK. The thermal conductivity of aluminum is approximately 237 W/mK.

In any of the embodiments to be described, the heat transfer member may be made from any of a variety of materials whose thermal conductivity is higher than that of the metal member. By way of example, the heat transfer member may be made from any one or more or a variety of diamond materials that exhibit a thermal conductivity much higher than that of copper or aluminum. Examples of such diamond materials include several commercially available metal-diamond composites such as a copper-diamond (Cu-Diamond) composite, a silver-diamond (Ag-Diamond) composite, and an aluminum-diamond (Al-Diamond) composite. In these and other diamond materials, synthetic diamond components may be included, such as chemical vapor deposition (CVD) diamond components as well as single-crystal diamond components. The thermal conductivity of metal-diamond composites can be as high as 2200 W/mK. For example, one commercially available diamond particle composite material in sheet form exhibits a thermal conductivity of approximately 800 W/mK. Other very high thermal conductivity materials may be used in embodiments as well.

In several embodiments to be described, one or more volumes of thermal interface material (“TIM”) are included to thermally couple one or more components to one or more other components. In such embodiments, any suitable thermal interface materials may be used, taking the needs of a particular application into consideration. As persons having skill in the art will appreciate, general categories of thermal interface materials used in IC packaging applications include polymer type TIMs such as those based on a silicone matrix, film type TIMs such as graphite-based or polyimide sheets, and metal type TIMs such as solder. For example, one common class of TIMs comprises a polymer matrix such as an epoxy or silicone resin with thermally conductive fillers such as boron nitride, alumina, aluminum, zinc oxide, or silver. Other materials may also be used. While the thermal conductivity of a given thermal interface material will vary depending on a number of factors including its size and composition, in general the thermal conductivity of a TIM volume in the embodiments to be described below is less than or equal to that of the metal member in the described embodiment.

In each described embodiment, a “hybrid material” lid or heat sink or cold plate is one that is constructed using two different materials: (1) a metal material from which a main body or frame of the lid, heat sink, or cold plate is constructed; and (2) an ultra-high thermal conductivity material that is attached to the main body or frame of the lid, heat sink, or cold plate. In each case, the ultra-high conductivity material has a substantially higher thermal conductivity than that of the metal body or frame to which it is attached. As a non-limiting example, in some embodiments, a volume of diamond composite material having a thermal conductivity of approximately 800 W/mK may be attached to a copper lid, heat sink or cold plate that has a thermal conductivity of approximately 400 W/mK. The resulting hybrid component will exhibit enhanced thermal conductivity relative to a lid, heat sink, or cold plate made from copper alone. Moreover, the resulting hybrid component will be easier and less expensive to manufacture than would be a lid, heat sink, or cold plate made entirely from a diamond composite material. In addition, the hybrid component will be more mechanically robust than would be a lid, heat sink, or cold plate made entirely from a diamond composite material.

The phrase “high conductivity heat transfer member” and the like as used herein in relation to a component that is attached to or is designed to be attached to a metal member (e.g., to a package lid, a heat sink, or a cold plate) means a component having a higher thermal conductivity than that of the metal member to which it is attached. By way of example, in embodiments wherein the metal member comprises copper or aluminum and the heat transfer member comprises a diamond material, the thermal conductivity of the heat transfer member may be at least 2 times that of the metal member. Other material combinations may also be chosen that yield a substantially higher thermal conductivity for the heat transfer member than that of the metal member, such as 1.5 times higher, 2 times higher, or more.

### Die Mounting Arrangements and Numbers of Dies

In the example embodiments that follow, one or more dies are mounted to a package substrate. In any such embodiments, the dies may be mounted to the substrate directly, or they may be mounted to the substrate indirectly, as through one or more interposers or through one or more other dies arranged in stacked fashion over the substrate. Although each example embodiment employs one or the other of such techniques, it should be understood in each case that analogous embodiments may also be constructed wherein the dies are mounted to the substrate using a technique other than the one illustrated. In addition, the number of dies shown in the illustrated embodiments is by way of example only. It should be understood in each case that analogous embodiments may be constructed that include a different number of dies than is shown the illustrated embodiment, such as a single die in some embodiments, or two or more dies in other embodiments.

Moreover, in any embodiments, the top surfaces of the respective dies need not be disposed at the same height relative to the package substrate to which the dies are directly or indirectly mounted. Rather, top surfaces of the dies may be disposed at different heights. In the latter case, height compensation may be provided with heat transfer components whose thicknesses complement the heights of the respective dies, as will become more clear in the context of the discussion of the examples that follow.

### Example Hybrid Material Package Lids, Heat Sinks, or Cold Plates

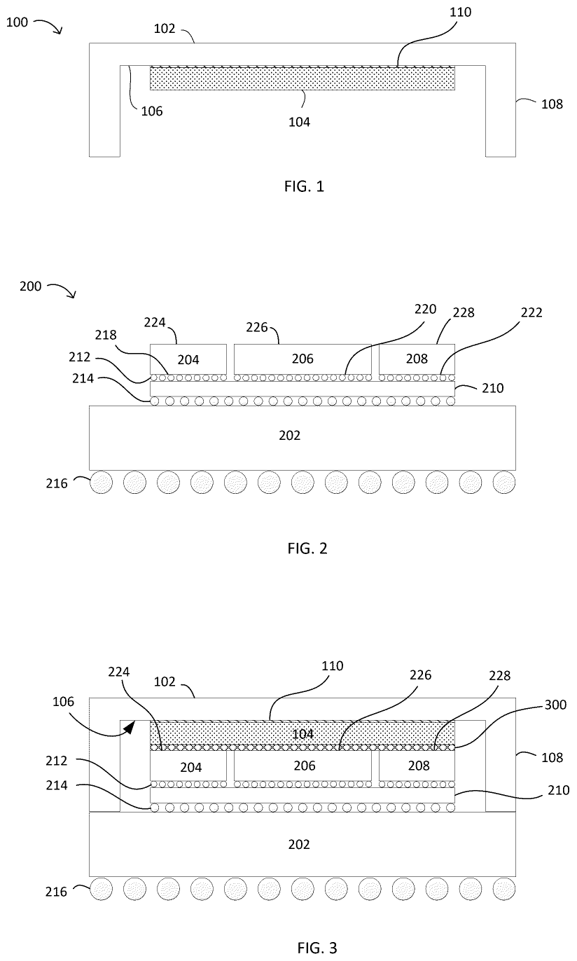

FIG. 1 is a sectional side view illustrating an example hybrid material IC package lid 100 in accordance with some embodiments. IC package lid 100 comprises a metal member 102 and a heat transfer member 104 having a higher thermal conductivity than that of the metal member. The package lid is designed to be placed above a package substrate on which one or more IC dies are mounted, such that the lid covers the dies and at least the part of the package substrate on which they are mounted. When the lid is so arranged over a substrate, a bottom side 106 of the lid faces the substrate while a peripheral flange 108 of the lid rests on the substrate. In the embodiment shown, the heat transfer member is attached to the lid on the bottom side 106 of the lid. In some embodiments, the heat transfer member may be attached to the lid using a brazing or soldering material 110. Other attachment materials may also be used. Because the attachment material in the illustrated embodiment becomes part of a thermal conduction path from a die to the package lid during operation of the IC package, the attachment material used is selected to have a higher melting point than the expected operating temperature of the completed assembly.

FIG. 2 is a sectional side view illustrating an example IC package 200 to which lid 100 may be applied. IC package 200 includes a package substrate 202 on which three IC dies 204, 206, 208 are mounted. In the illustrated embodiment, the dies are mounted to the substrate indirectly via an interposer 210. Bottom surfaces 218, 220, 222 of the dies face toward the package substrate, while top surfaces of the dies define respective die top areas 224, 226, 228 that face away from the package substrate. Electrical contacts or pads disposed on the bottom surfaces of the dies are coupled via solder connections 212 to the top side of the interposer. Meanwhile electrical contacts or pads disposed on the bottom side of the interposer are coupled via solder connections 214 to the top side of the substrate, and additional electrical contacts or pads 216 are provided on the bottom side of the package substrate for connection to a socket or to a printed circuit board (“PCB”).

FIG. 3 is a sectional side view illustrating the lid of FIG. 1 applied to the IC package of FIG. 2 in accordance with some embodiments. As can be seen in the drawing, metal member 102 is disposed above at least the part of the substrate on which the dies are mounted, such that the bottom side 106 of the member faces the substrate. Peripheral flange 108 may be attached to the substrate using any suitable technique, such as by brazing or soldering, or by using an adhesive such as an epoxy resin.

In the illustrated embodiment, the lid is placed over the substrate in a manner such that heat transfer member 104 is disposed over all three of die top areas 224, 226, 228.

As FIG. 3 illustrates, a volume 300 of thermal interface material (“TIM”) is disposed between the heat transfer member and the die top areas such that a top side of the TIM volume is in contact with the heat transfer member and a bottom side of the TIM volume is in contact with the die top areas. In this manner, thermal conduction paths are established from each respective die top area to metal member 102. Each such path passes through the TIM volume, the heat transfer member, and attachment material 110.

In the illustrated embodiment, a single unified TIM volume covers all three die top areas 224, 226, 228 such that different portions of the single TIM volume cover the respective separate die top areas. In other embodiments, distinct TIM volumes may be used to cover the die top areas separately.

In general, the sizes and locations of heat transfer member 104 and TIM volume(s) 300 may be designed such that they cover a single die or any number of two or more dies.

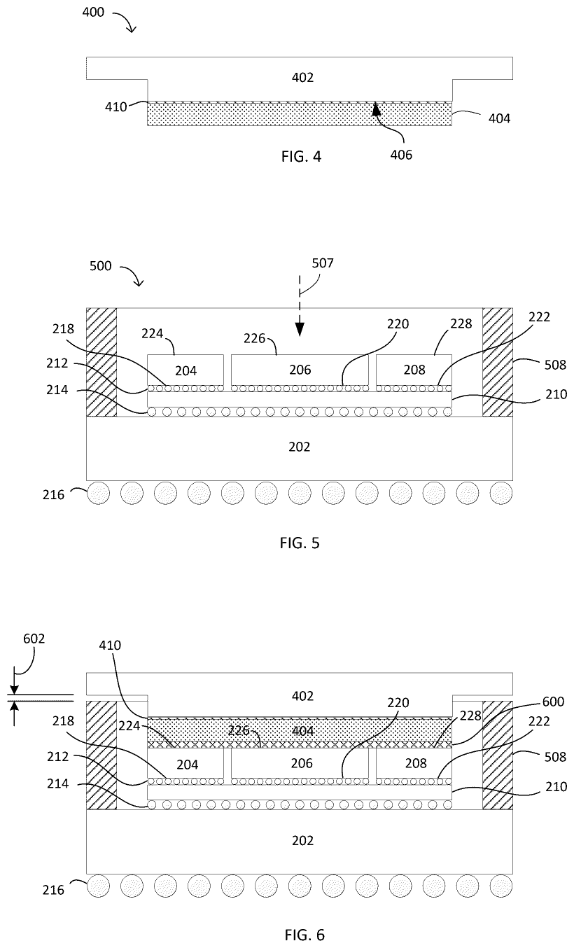

FIGS. 4-6 are sectional side views illustrating a lidless IC package wherein a hybrid material heat sink or cold plate is designed to fit over the package in a manner analogous to that of the hybrid lid of FIGS. 1-3.

Referring now to FIG. 4, heat sink or cold plate 400 includes a metal member 402 and a heat transfer member 404 having a higher thermal conductivity than that of the metal member. The heat sink or cold plate is designed to be placed above a package substrate on which one or more IC dies are mounted, such that the heat sink or cold plate covers the dies and at least the part of the package substrate on which they are mounted. When the heat sink or cold plate is so arranged over a substrate, a bottom side 406 of the heat sink or cold plate faces the substrate. In the embodiment shown, the heat transfer member is attached to the heat sink or cold plate on the bottom side 406 of the heat sink or cold plate. The heat transfer member may be attached to the heat sink or cold plate using a brazing or soldering material 410. Other attachment materials may also be used. Because the attachment material in the illustrated embodiment becomes part of a thermal conduction path from a die to the package heat sink or cold plate during operation of the IC package, the attachment material used is selected to have a higher melting point than the expected operating temperature of the completed assembly.

FIG. 5 is a sectional side view illustrating an example lidless IC package 500 to which heat sink or cold plate 400 may be applied. IC package 500 is similar to IC package 200 in that it includes a package substrate 202 on which three IC dies 204, 206, 208 are mounted via an interposer 210. Bottom surfaces 218, 220, 222 of the dies face toward the package substrate, while top surfaces of the dies define respective die top areas 224, 226, 228 that face away from the package substrate. As in the example of FIG. 2, electrical contacts or pads disposed on the bottom surfaces of the dies are coupled via solder connections 212 to the top side of the interposer. Meanwhile electrical contacts or pads disposed on the bottom side of the interposer are coupled via solder connections 214 to the top side of the substrate, and additional electrical contacts or pads 216 are provided on the bottom side of the package substrate for connection to a socket or to a PCB. Unlike the example of FIG. 2, a lidless package such as package 500 typically includes a structural wall or ring 508 that surrounds the area of the substrate on which the dies are mounted. Like flange 108, structural wall 508 may be attached to the substrate using any suitable technique, such as by brazing or soldering, or with the use of an adhesive such as an epoxy resin. The structural wall does not cover the die top areas, such that the die top areas are exposed from above as indicated at 507.

FIG. 6 is a sectional side view illustrating the heat sink or cold plate of FIG. 4 applied to the IC package of FIG. 5 in accordance with some embodiments. As can be seen in the drawing, metal member 402 is disposed above at least the part of the substrate on which the dies are mounted, such that the bottom side 406 of the metal member faces the substrate. In the illustrated embodiment, the heat sink or cold plate is placed over the substrate in a manner such that heat transfer member 404 is disposed over all three of die top areas 224, 226, 228.

A volume 600 of thermal interface material is disposed between the heat transfer member and the die top areas such that a top side of the TIM volume is in contact with the heat transfer member and a bottom side of the TIM volume is in contact with the die top areas. In this manner, thermal conduction paths are established from each respective die top area to metal member 402. Each such path passes through the TIM volume, the heat transfer member, and attachment material 410.

In the illustrated embodiment, a single unified TIM volume covers all three die top areas 224, 226, 228 such that different portions of the single TIM volume cover the respective separate die top areas. In other embodiments, distinct TIM volumes may be used to cover the die top areas separately.

In general, the sizes and locations of heat transfer member 404 and TIM volume(s) 600 may be designed such that they cover a single die or any number of two or more dies.

Depending on the needs of the application at hand, heat sink or cold plate 400 may or may not be designed to rest on structural wall 508 in the final assembly. In the illustrated embodiment, a small gap is shown at 602 by way of example to represent embodiments in which the heat sink or cold plate is designed not to rest on the top of the structural wall.

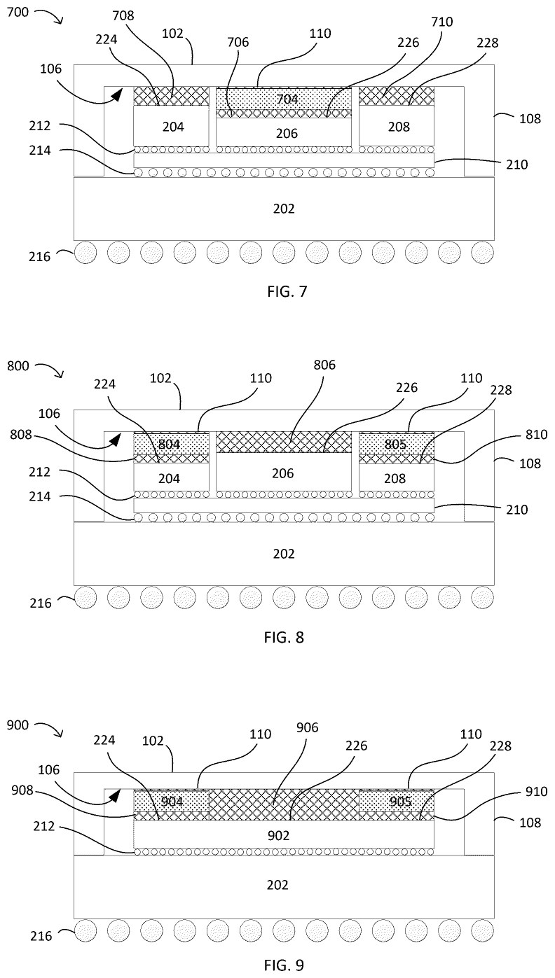

In further embodiments that involve multi-die IC packages, some of the dies in the package may be provided with heat transfer paths that include a high conductivity heat transfer member such as those described above, while other dies in the package may transfer heat through paths that do not include a high conductivity heat transfer member. FIGS. 7-12 illustrate several examples of such embodiments.

Referring now to the example of FIG. 7, an IC package 700 may include components arranged similarly to those shown in the embodiment of FIG. 3 except that, in IC package 700, only one of the dies is thermally coupled to a high conductivity heat transfer member, while the other dies in the package are provided with heat transfer paths that do not include a high conductivity heat transfer member. Specifically, package 700 includes a single heat transfer member 704 having a higher thermal conductivity than that of metal member 102. The top of the heat transfer member is attached to metal member 102, such as by using brazing or soldering material 110, at a location such that the heat transfer member will be disposed over only die top area 226 when the metal member is attached to the package substrate. TIM volume 706 thermally couples the bottom of heat transfer member 704 to die top area 226. Meanwhile, TIM volume 708 is disposed between die top area 224 such that the bottom side of TIM volume 708 is in contact with the die top area and the top side of the TIM volume is in contact with the metal member. Similarly, TIM volume 710 is disposed between die top area 228 such that the bottom side of TIM volume 710 is in contact with the die top area and the top side of the TIM volume is in contact with the metal member. In this arrangement, while all three dies are provided with heat transfer paths from their respective die top areas to the metal member, only die 206 is provided with a heat transfer path that includes high conductivity heat transfer member 704.

In some embodiments, two or more separate heat transfer members may be coupled to respective separate die top areas in the same IC package. The separate die top areas may be disposed on separate dies (e.g., on separate high-heat dies inside the same package), or they may be disposed on the same die (e.g., on two distinct high-heat areas of a single die). FIG. 8 illustrates an example of the former case, while FIG. 9 illustrates an example of the latter case.

Referring now to the example of FIG. 8, an IC package 800 may include components arranged similarly to those of IC package 700 except that, in IC package 800, two of the dies are thermally coupled to separate high conductivity heat transfer members, while another one of the dies is provided with a heat transfer path that does not include a high conductivity heat transfer member. Specifically, package 800 includes two discrete heat transfer members 804, 805, each of which has a higher thermal conductivity than that of metal member 102. The tops of the heat transfer members are attached to metal member 102, such as by using brazing or soldering material 110, at locations such that the heat transfer members will be disposed over die top areas 224 and 228, respectively, when the metal member is attached to the package substrate. The bottom surface of TIM volume 808 is in contact with die top area 224, and the top surface of TIM volume 808 is in contact with the bottom of heat transfer member 804. Similarly, the bottom surface of TIM volume 810 is in contact with die top area 228, and the top surface of TIM volume 810 is in contact with the bottom of heat transfer member 805. Meanwhile, TIM volume 806 is disposed between die top area 226 and the metal member such that the bottom side of TIM volume 708 is in contact with the die top area and the top side of the TIM volume is in contact with the metal member. In this arrangement, while all three dies are provided with heat transfer paths from their respective die top areas to the metal member, dies 204 and 208 are provided with heat transfer paths that include separate high conductivity heat transfer members, and die 206 is provided with a heat transfer path that does not include a high conductivity heat transfer member.

Referring now to FIG. 9, an IC package 900 may include components arranged similarly to those of IC packages 700 and 800 except that, in IC package 900, two distinct die top areas on a single die are thermally coupled to separate high conductivity heat transfer members 904, 905, while another die top area of the same die is provided with a heat transfer path that does not include a high conductivity heat transfer member.

IC package 900 also illustrates a case in which the die is coupled to the package substrate directly, instead of indirectly such as through an interposer or through another die. Specifically, in the example of FIG. 9, electrical contacts or pads 212 on the bottom surface of die 902 are electrically connected directly to corresponding contacts or pads on package substrate 202 instead of through an interposer. As was mentioned above, in any embodiments, other techniques may be used to electrically couple the die or dies to the package substrate.

In package 900, die top areas 224 and 228 represent high-temperature areas of die 902, while die top area 226 represents a lower-temperature area of die 902. The package includes two discrete heat transfer members 904, 905, each of which has a higher thermal conductivity than that of metal member 102. The tops of the heat transfer members are attached to metal member 102, such as by using brazing or soldering material 110, at locations such that the heat transfer members will be disposed over die top areas 224 and 228, respectively, when the metal member is attached to the package substrate.

The bottom side of TIM volume 908 is in contact with die top area 224, and the top side of the TIM volume is in contact with the bottom surface of heat transfer member 904. Similarly, the bottom side of TIM volume 910 is in contact with die top area 228, and the top side of the TIM volume is in contact with the bottom surface of heat transfer member 905. Meanwhile, TIM volume 906 is disposed between die top area 226 and the metal member such that the bottom side of TIM volume 906 is in contact with the die top area and the top side of the TIM volume is in contact with the metal member. Thus, in this arrangement, while all three dies are provided with heat transfer paths from their respective die top areas to the metal member, die top areas 224 and 228 are provided with heat transfer paths that include separate high conductivity heat transfer members, and die top area 226 is provided with a heat transfer path that does not include a high conductivity heat transfer member.

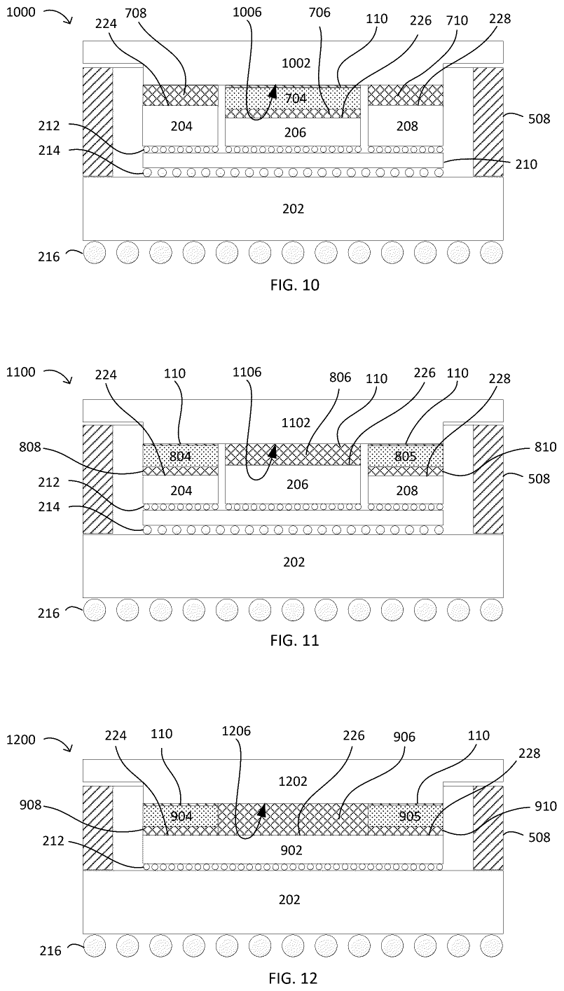

FIGS. 10-12 are sectional side views illustrating lidless IC packages wherein hybrid material heat sinks or cold plates are designed to fit over the packages in a manner analogous to that of the packages lids in the examples of FIGS. 7-9, respectively.

Referring now to FIG. 10, lidless IC package 1000 is analogous to the lidded package of example of FIG. 7 in that one of the dies in package 1000 is provided with a heat transfer path that includes a high conductivity heat transfer member, whereas two other dies in the package are provided with heat transfer paths that do not include a high conductivity heat transfer member. In package 1000, metal member 1002 comprises a heat sink or a cold plate, and heat transfer member 704 has a higher thermal conductivity than that of the metal member. Surface 1006 of the metal member is configured to face the package substrate. The bottom surface of TIM volume 706 is in contact with die top area 226, and the top surface of the TIM volume is in contact with the bottom of the heat transfer member. The top of the heat transfer member is attached to surface 1006 of the metal member, such as with brazing or soldering material 110. The bottom surface of TIM volume 708 is in contact with die top area 224, and the top surface of the TIM volume is in contact with the metal member. Similarly, the bottom surface of TIM volume 710 is in contact with die top area 228, and the top surface of the TIM volume is in contact with the metal member. In this arrangement, die 206 is provided with a heat transfer path that includes high conductivity heat transfer member 704, while dies 204 and 208 are provided with heat transfer paths that do not include a high conductivity heat transfer member.

Referring now to FIG. 11, lidless IC package 1100 is analogous to the lidded package of example of FIG. 8 in that two of the dies in package 1100 are provided with heat transfer paths that include distinct high conductivity heat transfer members, whereas another die in the package is provided with a heat transfer path that does not include a high conductivity heat transfer member. In package 1100, metal member 1102 comprises a heat sink or a cold plate, and heat transfer members 804, 805 each have a higher thermal conductivity than that of the metal member. Surface 1106 of the metal member is configured to face the package substrate. The top surfaces of each of heat transfer members 804, 805 are attached to surface 1106 of the metal member, such as with brazing or soldering material 110. The bottom surface of TIM volume 808 is in contact with die top area 224, and the top surface of the TIM volume is in contact with the bottom of heat transfer member 804. Similarly, the bottom surface of TIM volume 810 is in contact with die top area 228, and the top surface of the TIM volume is in contact with the bottom of heat transfer member 805. Meanwhile, the bottom surface of TIM volume 806 is in contact with die top area 226, and the top surface of the TIM volume is in contact with the metal member. In this arrangement, dies 204 and 208 are provided with respective heat transfer paths that include a distinct high conductivity heat transfer member, while die 206 is provided with a heat transfer path that does not include a high conductivity heat transfer member.

Referring now to FIG. 12, lidless IC package 1200 is analogous to the lidded package of example of FIG. 9 in that two distinct die top areas on a single die are provided with heat transfer paths that include a distinct high conductivity heat transfer member, whereas another die top area on the same die is provided with a heat transfer path that does not include a high conductivity heat transfer member. In package 1200, metal member 1202 comprises a heat sink or a cold plate, and each of heat transfer members 904, 905 has a higher thermal conductivity than that of the metal member. Surface 1206 of the metal member is configured to face the package substrate. The top surfaces of each of heat transfer members 904, 905 are attached to surface 1206 of the metal member, such as with brazing or soldering material 110. The bottom surface of TIM volume 908 is in contact with die top area 224, and the top surface of the TIM volume is in contact with the bottom of heat transfer member 904. Similarly, the bottom surface of TIM volume 910 is in contact with die top area 228, and the top surface of the TIM volume is in contact with the bottom of heat transfer member 905. Meanwhile, the bottom surface of TIM volume 906 is in contact with die top area 226, and the top surface of the TIM volume is in contact with the metal member. In this arrangement, die top areas 224 and 228 are provided with respective heat transfer paths that include a high conductivity heat transfer member, while die top area 226 on the same die is provided with a heat transfer path that does not include a high conductivity heat transfer member.

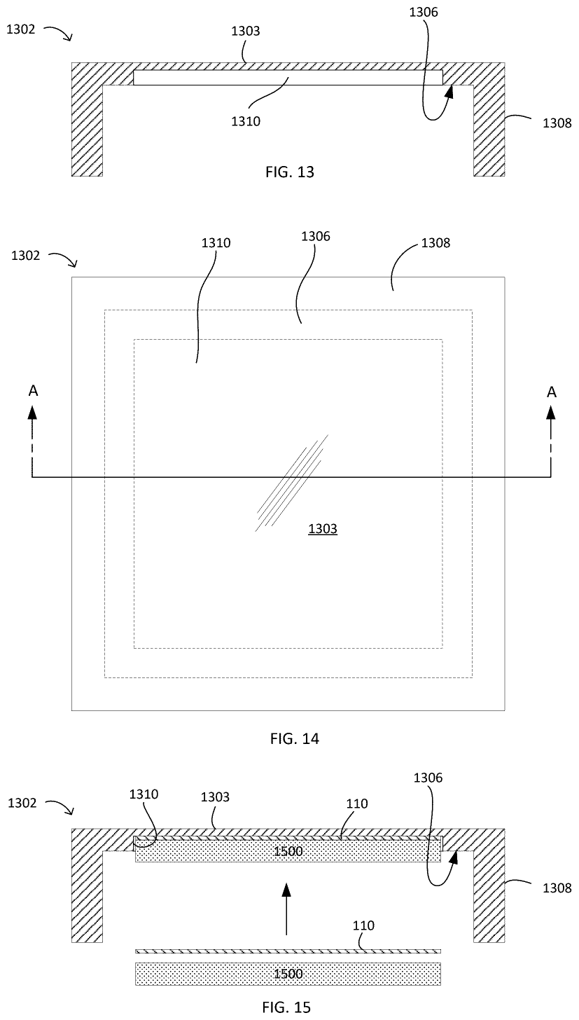

In any of the foregoing types of embodiments, any of the heat transfer members may be disposed in a recess formed in a surface of the metal member that is configured to face the package substrate. Doing so may further reduce the thermal resistance of the heat transfer path between a die top area and the top surface of the metal member. FIGS. 13, 14, and 15 are provided to illustrate this technique in more detail.

Referring now to FIGS. 13, 14, and 15, an example metal member 1302 comprises a package lid that includes a peripheral flange 1308 for engaging with a package substrate. Surface 1306 of the metal member is configured to face the package substrate when the lid is attached over the substrate. As can be seen from the drawings, a recess 1310 is formed in surface 1306 of the metal member. A heat transfer member 1500 having a higher thermal conductivity than that of the metal member may be disposed completely or partially inside recess 1310 and attached to the metal member, for example with brazing or soldering material 110. Disposing a heat transfer member within such a recess formed in the metal member may further reduce a heat transfer path that passes through the heat transfer member to a top surface 1303 of the metal member. To aid in assembly and manufacture, the shape and size of the recess may be designed to correspond to the shape and size of the heat transfer member so that the recess itself acts as a guide during the assembly and attachment of the heat transfer member to the metal member. If desired, a heat sink or a cold plate may be thermally coupled to top surface 1303 of the metal member.

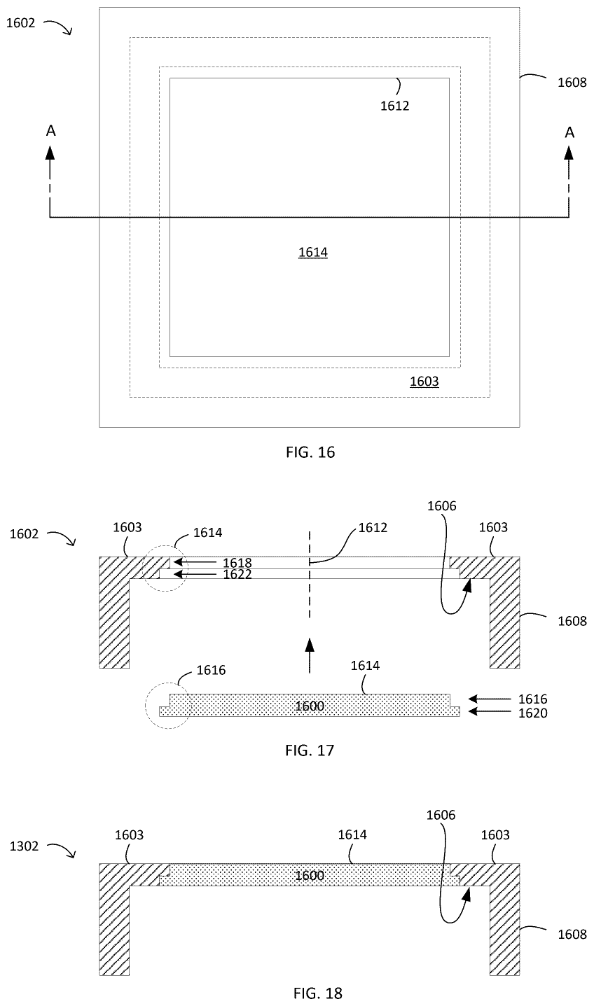

In further embodiments, any one or more of the heat transfer members may be disposed in a through hole formed in the metal member. FIGS. 16-22 are provided to illustrate this technique in more detail.

Referring now to FIGS. 16, 17, and 18, an example metal member 1602 comprises a package lid that includes a peripheral flange 1608 for engaging with a package substrate. Surface 1606 of the metal member is configured to face the package substrate when the lid is attached over the substrate. As can be seen from the drawings, a through hole 1612 is formed in surface 1606 of the metal member. A heat transfer member 1600 having a higher thermal conductivity than that of the metal member may be disposed inside the through hole such that at least a portion 1614 of the heat transfer member is exposed at a top side 1603 of the metal member as shown, for example, in FIG. 18.

In various embodiments, the shape and size of the through hole may be designed to correspond to the shape and size of the heat transfer member, so that the through hole itself acts as a guide during the assembly and attachment of the heat transfer member to the metal member.

To further aid in assembly and manufacture in any embodiments that utilize the through hole technique, and to provide enhanced mechanical reliability in such embodiments, the through hole and the heat transfer member may comprise complementary stepped cross sectional profiles 1614, 1616. The complementary profiles may take a variety of shapes. For example, in the illustrated embodiment, a narrower portion 1616 of the heat transfer member fits within a narrower portion 1618 of the through hole, and a wider portion 1620 of the heat transfer member fits within a wider portion 1622 of the through hole. In some embodiments, the narrower portions may be disposed on the top side 1603 of the metal member, while the wider portions may be disposed on the bottom side 1606 of the metal member, so that the stepped profile helps to counteract upward forces that may be exerted on the heat transfer member by components disposed below it.

In any embodiments that utilize the through hole technique, the heat transfer member may be attached to the metal member in a variety of ways. In some embodiments, the heat transfer member may be attached with brazing or soldering material applied around inside surfaces of the through hole. In other embodiments, the heat transfer member may be attached with a high temperature resin applied around inside surfaces of the through hole. In embodiments wherein the resin is applied on inside surfaces of the wider portion 1622 of the metal member and wherein a die top area is disposed below the narrower portion 1616 of the heat transfer member, the high temperature resin may, if desired, have a melting point below that of brazing or soldering material, as the resin itself in such embodiments will not be disposed in the resulting heat transfer path from the die top area to the exposed portion 1614 of the heat transfer member.

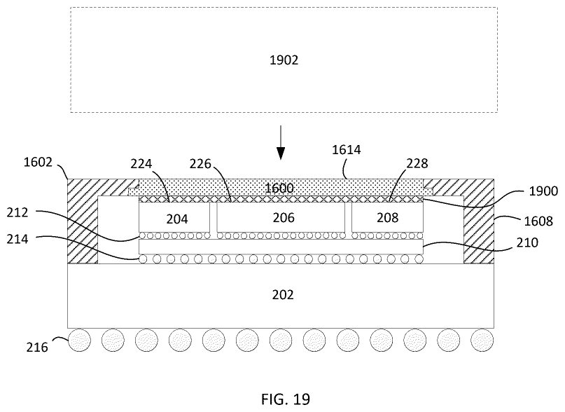

Referring now to FIG. 19, the bottom surface of heat transfer member 1600 may be thermally coupled to one or more die top areas in an IC package in any suitable manner, such as via one or more TIM volumes 1900. For example, in the illustrated embodiment, die top areas 224, 226, and 228 are in contact with the bottom surface of TIM volume 1900, and the top surface of TIM volume 1900 is in contact with the bottom surface of heat transfer member 1600. Other configurations may also be used such as, for example, any those described above. If desired, a heat sink or a cold plate 1902 may be thermally coupled to the exposed portion 1614 of the heat transfer member, as indicated by the downward arrow in the drawing.

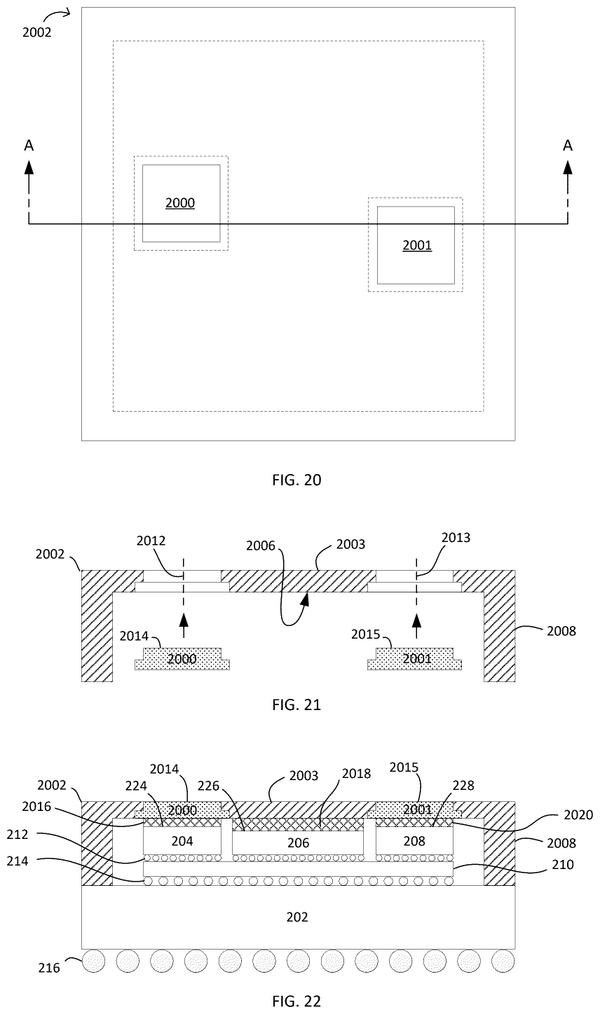

Any of the above-described techniques may be further extended to embodiments wherein the metal member defines two or more through holes. FIGS. 20, 21, and 22 are provided to illustrate an example of such embodiments.

Referring now to FIGS. 20, 21, and 22, an example metal member 2002 comprises a package lid that includes a peripheral flange 2008 for engaging with a package substrate 202. Surface 2006 of the metal member is configured to face the package substrate when the lid is attached over the substrate. As can be seen from the drawings, two through holes 2012, 2013 are formed in surface 2006 of the metal member. Heat transfer members 2000, 2001, each having a higher thermal conductivity than that of the metal member, may be disposed inside the respective through holes such that at least a portion 2014, 2015 of each heat transfer member is exposed at a top side 2003 of the metal member as shown, for example, in FIG. 22. The heat transfer members may be attached to the metal member according to any of the techniques described above.

The metal member may be attached to a package substrate to create an IC package such as, for example, IC package 2200 illustrated in FIG. 22. In IC package 2200, the bottom surface of TIM volume 2016 is in contact with die top area 224, and the top surface of the TIM volume is in contact with the bottom of heat transfer member 2000. Similarly, the bottom surface of TIM volume 2020 is in contact with die top area 228, and the top surface of the TIM volume is in contact with the bottom of heat transfer member 2001. Meanwhile, the bottom surface of TIM volume 2018 is in contact with die top area 226, and the top surface of the TIM volume is in contact with the metal member. Other IC die and package configurations may also be created that utilize two or more heat transfer members disposed in respective through holes of the metal member, including any of the IC die and package configurations described above.

### Methods of Manufacture

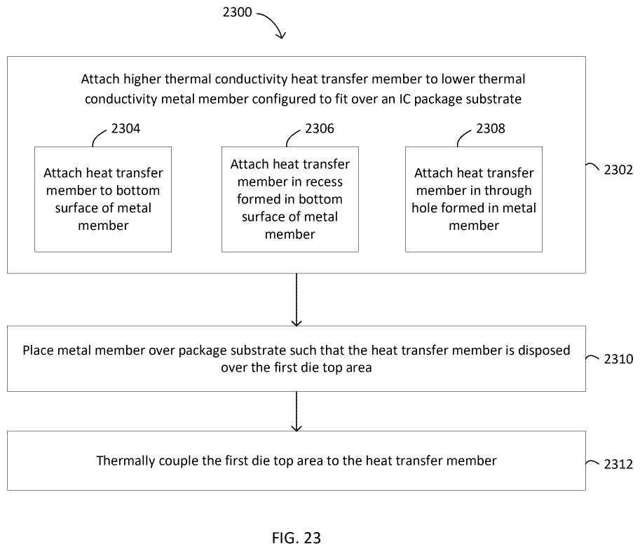

FIG. 23 is a flow diagram illustrating an example class of methods 2300 that may be used to manufacture any of the embodiments described above.

Beginning at step 2302, a first heat transfer is attached to a metal member that is configured to fit over an IC package substrate to which one or more dies are directly or indirectly coupled in a manner such that bottom surfaces of the dies face the package substrate and top surfaces of the dies define die top areas. The first heat transfer member has a thermal conductivity higher than the thermal conductivity of the metal member to which it is attached. The metal member may comprise, for example, a package lid, a heat sink, or a cold plate. In some embodiments, the metal member may comprise copper or aluminum, and the heat transfer member may comprise a diamond material having a thermal conductivity at least 1.5 times that of the metal member.

The attachment of the first heat transfer member to the metal member may be accomplished in a variety of ways, as described above. For example, the heat transfer member may be attached to a bottom surface of the metal member, as indicated at 2304, the heat transfer member may be attached in a recess formed in the bottom surface of the metal member, as indicated at 2306, or the heat transfer member may be attached in a through hole formed in the metal member, as indicated at 2308, in a manner such that at least a portion of the heat transfer member is exposed on a side of the metal member that is configured to face away from the package substrate. In some embodiments, attaching the heat transfer member to the metal member may comprise brazing or soldering the heat transfer member to the metal member. In other embodiments, the attachment may be accomplished with a high temperature resin, as was described above.

After attaching the first heat transfer member to the metal member, at step 2310 the metal member is placed over the package substrate in a manner such that the first heat transfer member is disposed over a first die top area.

In step 2312, thermal coupling is established between the first die top area and the first heat transfer member.

The thermal coupling may be direct or indirect, and the step of establishing the thermal coupling may be performed before, during, or after the step of placing the metal member over the package substrate. For example, in some embodiments, the thermal coupling may be established by disposing a volume of thermal interface material (a “TIM volume”) between the first die top area and the bottom surface of the first heat transfer member. In such embodiments, the TIM volume may be applied to the first die top area or to the bottom surface of the metal member before the metal member is placed over the package substrate. In other embodiments, the TIM volume may be injected between the first die top area and the bottom of the metal member after the metal member has been placed over the package substrate. In either case, in the final assembly, the bottom surface of the TIM volume is in contact with the first die top area and the top surface of the TIM volume is in contact with the bottom surface of the first heat transfer member.

In some embodiments, a second die top area distinct from the first die top area may be thermally coupled to the first heat transfer member. The thermal coupling may be accomplished, for example, by disposing a second TIM volume between the second die top area and the first heat transfer member such that a bottom surface of the second TIM volume is in contact with the second die top area and a top surface of the second TIM volume is in contact with the first heat transfer member. In other embodiments, a second heat transfer member may be attached to the metal member, and the second die top area may be thermally coupled to the second heat transfer member, such as by disposing a second TIM volume between the second die top area and second heat transfer member in a similar manner. In such embodiments, the first and second die top areas may be disposed on separate dies, or they may be disposed at different locations on the same die.

Multiple specific embodiments have been described above and in the appended claims. Such embodiments have been provided by way of example and illustration. Persons having skill in the art and having reference to this disclosure will perceive various utilitarian combinations, modifications and generalizations of the features and characteristics of the embodiments so described. For example, steps in methods described herein may generally be performed in any order, and some steps may be omitted, while other steps may be added, except where the context clearly indicates otherwise. Similarly, components in structures described herein may be arranged in different positions or locations, and some components may be omitted, while other components may be added, except where the context clearly indicates otherwise.

What is claimed is:

1. Heat transfer apparatus, comprising:
an integrated circuit (“IC”) package that includes a package substrate and one or more dies coupled to the package substrate, wherein bottom surfaces of the dies face toward the package substrate and top surfaces of the dies define die top areas;
a metal member disposed above at least part of the package substrate and having a metal member thermal conductivity; and
a first heat transfer member attached to the metal member and disposed over a first die top area, wherein the first heat transfer member has a first thermal conductivity higher than the metal member thermal conductivity.

2. The apparatus of claim 1:
further comprising a first volume of thermal interface material (“first TIM volume”) disposed between the first heat transfer member and the first die top area such that a top side of the first TIM volume is in contact with the first heat transfer member and a bottom side of the first TIM volume is in contact with the first die top area.

3. The apparatus of claim 2, further comprising:
a second die top area distinct from the first die top area;
a second heat transfer member attached to the metal member and disposed over the second die top area, wherein the second heat transfer member has a second thermal conductivity higher than the metal member thermal conductivity; and
a second volume of thermal interface material (“second TIM volume”) disposed between the second heat transfer member and the second die top area such that a top side of the second TIM volume is in contact with the second heat transfer member and a bottom side of the second TIM volume is in contact with the second die top area.

4. The apparatus of claim 3, wherein:
the first die top area and the second die top area lie are on separate dies.

5. The apparatus of claim 3, wherein:
the first die top area and the second die top area are on a single die.

6. The apparatus of claim 3, wherein:
the first heat transfer member and the second heat transfer member are distinct.

7. The apparatus of claim 3, wherein:
the first heat transfer member and the second heat transfer member comprise respective portions of a single heat transfer member.

8. The apparatus of claim 3, wherein:
the first TIM volume and the second TIM volume are distinct.

9. The apparatus of claim 3, wherein:
the first TIM volume and the second TIM volume comprise respective portions of a single TIM volume.

10. The apparatus of claim 2:
further comprising a second die top area and a second volume of thermal interface material (“second TIM volume”); and
wherein the second TIM volume is disposed between the metal member and the second die top area such that a top side of the second TIM volume is in contact with the metal member and a bottom side of the second TIM volume is in contact with the second die top area.

11. The apparatus of claim 1, wherein:
the metal member comprises a package lid.

12. The apparatus of claim 11, wherein:
the package lid defines a first through hole; and
the first heat transfer member is disposed inside the first through hole such that at least a portion of the first heat transfer member is exposed at a top side of the package lid.

13. The apparatus of claim 12:
further comprising a heat sink or a cold plate thermally coupled to the exposed portion of the first heat transfer member.

14. The apparatus of claim 12, wherein:
the package lid further defines a second through hole; and
further comprising a second heat transfer member disposed inside the second through hole such that at least a portion of the second heat transfer member is exposed at a top side of the package lid;
wherein the second heat transfer member is thermally coupled to a second die top area in the IC package.

15. The apparatus of claim 12, wherein:
the first through hole and the first heat transfer member comprise stepped cross sectional profiles such that a narrower portion of the first heat transfer member exposed at the top side of the package lid fits within a narrower portion of the first through hole and a wider portion of the first heat transfer member facing the package substrate fits within a wider portion of the first through hole.

16. The apparatus of claim 12, wherein:
the heat transfer member is attached to the package lid with a high temperature resin.

17. The apparatus of claim 1, wherein:
the metal member comprises a heat sink or a cold plate.

18. The apparatus of claim 1, wherein:
a bottom side of the metal member faces the package substrate and defines a recess; and
the first heat transfer member is disposed at least partially inside the recess.

19. The apparatus of claim 1, wherein:
the first heat transfer member is brazed or soldered to the metal member.

20. The apparatus of claim 1, wherein:
the metal member comprises copper or aluminum.

21. The apparatus of claim 20, wherein:
the metal member comprises at least one material selected from the group consisting of: a copper-molybdenum alloy, a copper-tungsten composite, and an aluminum-silicon-carbide composite.

22. The apparatus of claim 1, wherein:
the first heat transfer member comprises a diamond material.

23. The apparatus of claim 22, wherein:
the first heat transfer member comprises at least one material selected from the group consisting of: a copper-diamond composite, a silver-diamond composite, an aluminum-diamond composite, synthetic chemical vapor deposition (“CVD” diamond, and synthetic single-crystal diamond.

24. A method of manufacturing heat transfer apparatus, comprising:
attaching a first heat transfer member to a metal member configured to fit over an integrated circuit package substrate to which one or more dies are coupled such that bottom surfaces of the dies face toward the package substrate and top surfaces of the dies define die top areas;
after attaching the first heat transfer member to the metal member, placing the metal member over the package substrate in a manner such that the first heat transfer member is disposed over a first die top area; and
thermally coupling the first die top area to the heat transfer member;
wherein the metal member has a metal member thermal conductivity and the first heat transfer member has a first thermal conductivity higher than the metal member thermal conductivity.

25. The method of claim 24, wherein:
attaching the first heat transfer member comprises brazing or soldering the first heat transfer member to a surface of the metal member configured to face the package substrate.

26. The method of claim 24, wherein:
attaching the first heat transfer member comprises disposing the first heat transfer member in a first through hole of the metal member such that at least a portion of the first heat transfer member is exposed on a side of the metal member configured to face away from the package substrate.

27. The method of claim 26, wherein:
disposing the first heat transfer member in the first through hole comprises fixing the first heat transfer member in the first through hole with a high temperature resin.

28. The method of claim 24, wherein:
attaching the first heat transfer member comprises disposing the first heat transfer member in a recess formed in a surface of the metal member configured to face the package substrate.

29. The method of claim 24, further comprising:
disposing a first volume of thermal interface material (“first TIM volume”) between the first heat transfer member and the first die top area such that a top side of the first TIM volume is in contact with the first heat transfer member and a bottom side of the first TIM volume is in contact with the first die top area when the metal member has been placed over the package substrate.

30. The method of claim 29, further comprising:
disposing a second volume of thermal interface material (“second TIM volume”) between the metal member and a second die top area distinct from the first die top area such that a top side of the second TIM volume is in contact with the metal member and a bottom side of the second TIM volume is in contact with the second die top area when the metal member has been placed over the package substrate.

31. The method of claim 24, further comprising:
attaching a second heat transfer member to the metal member, wherein the second heat transfer member has a second thermal conductivity higher than the metal member thermal conductivity; and
wherein the attaching the second heat transfer member and the placing are performed in a manner such that the second heat transfer member is disposed over a second die top area distinct from the first die top area.

32. The method of claim 31, wherein:
the first die top area and the second die top area are on separate dies.

33. The method of claim 31, wherein:
the first die top area and the second die top area are on a single die.

34. The method of claim 24, wherein:
the metal member comprises a package lid.

35. The method of claim 24, wherein:
the metal member comprises a heat sink or a cold plate.

36. The method of claim 24, wherein:
the metal member comprises copper or aluminum.

37. The method of claim 24, wherein:
the first heat transfer member comprises a diamond material.
